(19) United States
(12) Patent Application Publication
(10) Pub. No.: US 2016/0209460 A1
(43) Pub. Date: Jul. 21, 2016

(54) ORGANIC LIGHT-EMITTING DIODE DISPLAY AND METHOD OF TESTING CONTACT PAD THEREOF

(71) Applicant: Samsung Display Co., Ltd., Yongin-City (KR)

(72) Inventor: Kwangsoo Lee, Yongin-City (KR)

(21) Appl. No.: 14/730,823

(22) Filed: Jun. 4, 2015

(30) Foreign Application Priority Data
Jan. 21, 2015 (KR) 10-2015-0010033

(51) Int. Cl. G01R 31/26; G09G 3/20; G09G 3/32; H01L 27/32; H01L 51/00

(52) U.S. Cl. CPC G01R 31/2635; H01L 27/3248; H01L 27/3276; H01L 51/0031; G09G 3/3225; G09G 3/2003; G09G 2330/028; G09G 2300/0426

(57) ABSTRACT

An organic light-emitting diode (OLED) display and a method of testing a contact pad thereof are disclosed. In one aspect, the OLED display includes a display portion formed over a substrate, a contact pad electrically connected to the display portion, and a contact pad test unit formed between the contact pad and the substrate and configured to generate a test current path.

### INCORPORATION BY REFERENCE TO ANY PRIORITY APPLICATIONS

This application claims the benefit of Korean Patent Application No. 10-2015-0010033, filed on Jan. 21, 2015, in the Korean Intellectual Property Office, the disclosure of which is incorporated herein in its entirety by reference.

### BACKGROUND

1. Field

The described technology generally relates to an organic light-emitting diode display and a method of testing a contact pad thereof.

2. Description of the Related Technology

An organic light-emitting diode (OLED) display includes a matrix of OLEDs each receiving a driving signal from a thin film transistor (TFT), and self-emitting light to display a desired image.

In this regard, the TFT includes an active layer, a gate electrode, a source electrode, a drain electrode which are stacked on a substrate. Accordingly, when an electric current is supplied to the gate electrode through wiring lines formed on the substrate, the electric current flows through the source electrode and the drain electrode via the active layer, and at the same time, the electric current flows through a pixel electrode of the OLED that is connected to the drain electrode.

An OLED also includes a common electrode which faces the pixel electrode, and an emission layer formed between the pixel electrode and the common electrode. When an electric current flows through the pixel electrode, a voltage is formed between the opposite electrode and the pixel electrode. Thus, as light is emitted in the emission layer, an image is displayed from the collection of emitting OLEDs.

### SUMMARY OF CERTAIN INVENTIVE ASPECTS

One inventive aspect relates to an OLED display and a method of testing if a contact pad included in the OLED display is faulty or not.

Another aspect is an OLED display that includes a display portion on a substrate, a contact pad that is electrically connected to the display portion, and a contact pad test unit forming a testing current-flow path along with the contact pad.

The contact pad test unit can include a gate portion forming a capacitor which is capable of being charged or discharged along with the contact pad, an active portion facing the gate portion, and a source portion and a drain portion that are connected to different parts of the active portion, wherein, when the capacitor is discharged, electric current can flow from the source portion to the drain portion via the active portion.

The display portion can include a thin film transistor including an active layer, a gate electrode, a source electrode, and a drain electrode on the substrate, and an organic light-emitting device that is connected to the thin film transistor.

The gate portion, the source portion, and the drain portion of the contact pad test unit can be formed of the same material and on the same layer as the gate electrode of the thin film transistor.

The active portion of the contact pad test unit can be formed of the same material and on the same layer as the active layer of the thin film transistor.

The contact pad test unit can be provided in plural with respect to the contact pad.

Another aspect is a method of testing a contact pad of an OLED display, the method including preparing, on a substrate, a display portion, a contact pad that is connected to the display portion, and a contact pad test unit forming a testing current-flow path along with the contact pad; and testing if the contact pad is faulty or not by confirming a current-flow state through the contact pad test unit.

The contact pad test unit can include a gate portion forming a capacitor which is capable of being charged or discharged along with the contact pad, an active portion facing the gate portion, and a source portion and a drain portion that are connected to different parts of the active portion, and the testing of whether the contact pad is faulty or not can include charging the capacitor by generating a potential difference between the contact pad and the gate portion, stopping the charging of the capacitor and the discharging of the capacitor, and confirming if electric current flows from the source portion to the drain portion via the active portion according to the discharging of the capacitor.

When it is confirmed in the testing of whether the contact pad is faulty or not that the electric current flows from the source portion to the drain portion via the active portion, the contact pad can be determined as being good, and when it is confirmed in the testing of whether the contact pad is faulty or not that the electric current does not flow from the source portion to the drain portion via the active portion, the contact pad can be determined as being faulty.

As the contact pad test unit is provided in plural with respect to the contact pad, the testing of whether the contact pad is faulty or not can be performed with the plurality of contact pad test units.

Another aspect is an organic light-emitting diode (OLED) display, comprising: a display portion formed over a substrate; a contact pad electrically connected to the display portion; and a contact pad test unit formed between the contact pad and the substrate and configured to generate a test current path.

In the above OLED display, the contact pad test unit comprises a gate portion forming a capacitor with the contact pad, wherein the capacitor is configured to be charged or discharged, wherein the contact pad test unit further comprises i) an active portion facing the gate portion and ii) source and drain portions electrically connected to different portions of the active portion, and wherein the active portion is configured to flow current from the source portion to the drain portion when the capacitor is discharged.

In the above OLED display, the display portion comprises a thin film transistor (TFT) including an active layer, a gate electrode, a source electrode, and a drain electrode formed over the substrate, and an OLED electrically connected to the TFT.

In the above OLED display, the gate portion, the source portion, and the drain portion of the contact pad test unit are formed of the same material and formed on the same layer as the gate electrode of the TFT.

In the above OLED display, the active portion of the contact pad test unit is formed of the same material and formed on the same layer as the active layer of the TFT.

In the above OLED display, the contact pad test unit includes first and second contact pad test units adjacent to each other.

In the above OLED display, the width of the active portion is substantially the same as the width of the contact pad.

In the above OLED display, the contact pad is formed over the entire contact pad test unit.

Another aspect is a method of testing a contact pad of an organic light-emitting diode (OLED) display, the method comprising: preparing, over a substrate, a display portion, a contact pad electrically connected to the display portion, and a contact pad test unit configured to generate a test current path; and verifying a current-flow state at the contact pad test unit so as to determine whether the contact pad is faulty.

In the above OLED display, the contact pad test unit comprises a gate portion, wherein the gate portion and the contact pad comprise a capacitor configured to be charged or discharged, wherein the contact pad test unit further comprises i) an active portion facing the gate portion and ii) source and drain portions electrically connected to different portions of the active portion, and wherein the verifying comprises generating a potential difference between the contact pad and the gate portion so as to charge the capacitor, stopping the charging of the capacitor, discharging the capacitor, and confirming if electric current is flowing from the source portion to the drain portion via the active portion based on the discharging of the capacitor.

The above method further comprises: when the electric current is flowing, determining the contact pad as not faulty; and when the electric current is not flowing, determining that the contact pad is faulty.

In the above method, the contact pad test unit includes first and second contact pad test units adjacent to each other, and wherein the testing is performed with the first and second contact pad test units.

Another aspect is an organic light-emitting diode (OLED) display, comprising: a display area comprising an OLED and a thin film transistor (TFT) electrically connected to the OLED; a pad area electrically connected to the display area and including a testing transistor and a contact pad formed over the testing transistor, wherein the testing transistor includes a gate electrode, and wherein the gate electrode and the contact pad form a capacitor configured to store test charge configured to test the contact pad.

In the above method, the testing transistor further includes source and drain electrodes, wherein the capacitor is configured to discharge the test charge, wherein the testing transistor further includes i) an active portion facing the gate electrode and ii) source and drain electrodes electrically connected to opposing ends of the active portion, and wherein the active portion is configured to flow current including the discharged test charge from the source portion to the drain portion.

In the above method, the TFT includes an active layer, a gate electrode, a source electrode, and a drain electrode each formed over the substrate.

In the above method, the gate, source, and drain electrodes of the testing transistor are formed of the same material and formed on the same layer as the gate electrode of the TFT.

In the above method, the active portion of the testing transistor is formed of the same material and formed on the same layer as the active layer of the TFT.

In the above method, the testing transistor includes first and second testing transistors adjacent to each other.

In the above method, the width of the active portion is substantially the same as the width of the contact pad.

In the above method, the contact pad is formed over the entire testing transistor.

### BRIEF DESCRIPTION OF THE DRAWINGS

FIG. 1 illustrates a cross-sectional view of an OLED display according to an embodiment.

FIG. 2 illustrates a circuit diagram for describing configuration of a contact pad test unit included in the OLED display of FIG. 1.

FIG. 3 illustrates a flowchart of a process of testing a contact pad by using the contact pad test unit of FIG. 2.

FIG. 4 illustrates a cross-sectional view of an OLED display according to another embodiment.

### DETAILED DESCRIPTION OF CERTAIN INVENTIVE EMBODIMENTS

As the described technology allows for various changes and numerous embodiments, exemplary embodiments will be illustrated in the drawings and described in detail in the written description. The effect and feature of the described technology and methods of accomplishing the same will become apparent from the following description of the exemplary embodiments in detail, taken in conjunction with the accompanying drawings. The described technology can, however, be embodied in many different forms and should not be construed as limited to the exemplary embodiments set forth herein.

Hereinafter, the described technology will be described in detail with reference to the accompanying drawings, in which exemplary embodiments are shown. Like reference numerals in the drawings denote like elements, and thus repeated descriptions thereof will be omitted.

As used herein, the singular forms “a,” “an,” and “the” are intended to include the plural forms as well, unless the context clearly indicates otherwise.

It will be understood that the terms such as “include,” “comprise,” and “have” used herein specify the presence of stated features or components, but do not preclude the presence or addition of one or more other features or components.

It will be further understood that when a layer, region, or component is referred to as being “formed on” another layer, region, or component, it can be directly or indirectly formed on the other layer, region, or component. That is, for example, intervening layers, regions, or components can be present.

Sizes of components in the drawings can be exaggerated for convenience of explanation. In other words, since sizes and thicknesses of components in the drawings are arbitrarily illustrated for convenience of explanation, the following exemplary embodiments are not limited thereto.

When an embodiment can be implemented differently, a specific process order can be performed differently from the described order. For example, two consecutively described processes can be performed substantially at the same time or performed in an order opposite to the described order. In this disclosure, the term “substantially” includes the meanings of completely, almost completely or to any significant degree under some applications and in accordance with those skilled in the art. Moreover, “formed on” can also mean “formed over.” The term “connected” can include an electrical connection.

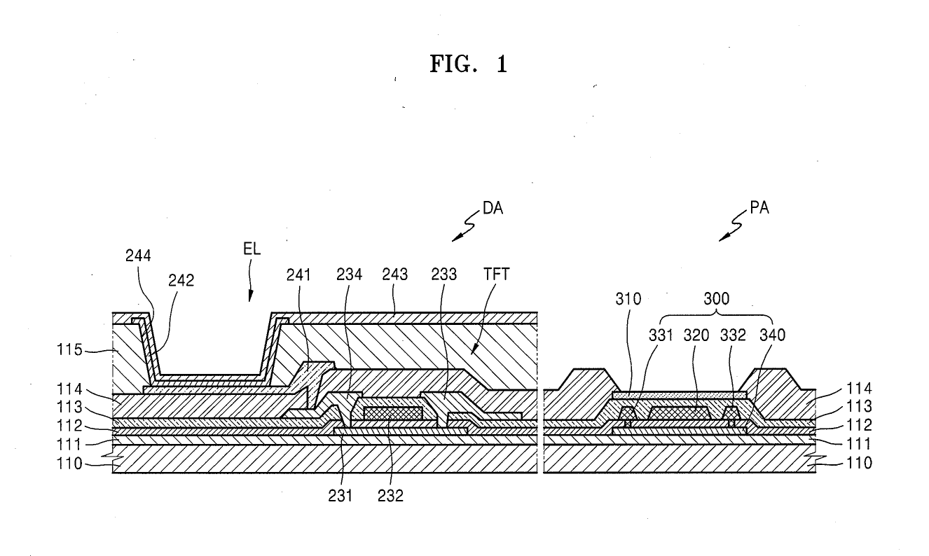

FIG. 1 illustrates a cross-sectional view of an OLED display according to an embodiment.

As illustrated in FIG. 1, a display area or display portion DA including an OLED EL and a thin film transistor (TFT) and a pad area PA including a contact pad 310 electrically connected to the display area DA are included in the OLED display.

First, the TFT includes an active layer 231 formed of an amorphous silicon thin film or a polycrystalline silicon thin film on an upper portion of a buffer layer 111 on a substrate 110. The active layer 231 has a source region and a drain region which are doped with N-type or P-type impurities of high concentration. For reference, the active layer 231 can be formed of an oxide semiconductor. For example, the oxide semiconductor includes an oxide of a material selected from a metal element of group 12, 13 or 14 such as zinc (Zn), indium (In), gallium (Ga), tin (Sn), cadmium (Cd), germanium (Ge) or hafnium (Hf) and a combination thereof. For example, the semiconductor active layer 231 includes G-I-Z-O[(In₂O₃)a(Ga₂O₃)b(ZnO)c] (in which a, b, and c are real numbers that respectively satisfy the conditions of a≧0, b≧0, and c>0).

As a first insulating layer 112 is formed on an upper portion of the active layer 231, a gate electrode 232 is formed on the first insulating layer 112. On an upper portion of the gate electrode 232, a source electrode 233 and a drain electrode 234 are formed, wherein the source electrode 233 is connected to a driving power line (not shown), and thus supplies a reference voltage for driving to the active layer 231. The drain electrode 234 connects the TFT to the OLED EL and thus applies a driving power to the OLED EL. A second insulating layer 113 is provided between the gate electrode 232 and the source and drain electrodes 233 and 234, and a passivation film 114 is formed between the source and drain electrodes 233 and 234 and a first electrode 241, which is an anode of the OLED EL.

An insulating planarization film 115 formed of acryl or the like is formed on an upper portion of the first electrode 241. After a predetermined opening portion 244 is formed in the planarization film 115, the above-described elements of the OLED EL are formed.

The OLED EL, which displays predetermined image information by emitting red, green, and blue light according to a flow of electric current, includes the first electrode 241, which is the anode connected to the drain electrode 234 and thus supplied with positive power from the drain electrode 234. The OLED EL also includes a second electrode 243 covering the entire pixel and supplying negative power, and an emission layer 242 formed between the first and second electrodes 241 and 243 and emitting light.

The first electrode 241, which is an anode, can include a transparent electrode formed of, for example, an indium tin oxide (ITO). In the case of a bottom-emission type display, in which light is emitted toward the substrate 110, the second electrode 243, which is a cathode, can be formed by depositing aluminum/calcium (Al/Ca) or the like. In the case where the display area DA is of a top-emission type display in which light is emitted in a direction of an encapsulation member (not shown) which faces the substrate 110, the second electrode 243 can be formed of a transparent material. For example, the second electrode 243 is formed such that after a semi-transmissive thin film is formed of a metal such as magnesium-silver (Mg—Ag), a transparent ITO is deposited thereon. The second electrode 243 can be formed in various patterns. The first electrode 241 and the second electrode 243 can be stacked in opposite positions than the ones shown.

A low-molecular or polymer organic film can be used for the emission layer 242, and a hole injection layer (HIL), a hole transport layer (HTL), an electron transport layer (ETL), an electron injection layer (EIL), and the like can be further stacked adjacent to the emission layer 242.

For reference, the emission layer 242 can be formed separately with respect to each pixel so that pixels emitting light of red, green, and blue colors gather to form one unit pixel or can be formed in common over the entire pixel region regardless of positions of the pixels. In this regard, the emission layer 242 can be formed, for example, such that layers including luminescent substances emitting light of red, green, and blue colors are vertically stacked on one another or combined with each other. Other colors can be combined if the combination emits white light. Also, the emission layer 242 can further include a color converting layer or a color filter that converts the emitted white light into light of a predetermined color.

Meanwhile, the TFT can be provided in plurality with respect to one OLED EL.

Next, a contact pad 310 and a contact pad test unit or contact pad test portion or testing transistor 300 are included in the pad area PA, wherein the contact pad 310 is electrically connected to the display area DA and the contact pad test unit 300 is used to determine whether the contact pad 310 is faulty (or defective) or not when necessary.

The contact pad test unit 300 includes a gate portion 320 facing the contact pad 310 and forming a capacitor along with the contact pad 310, an active portion 340 facing the gate portion 320, and a source portion 331 and a drain portion 332 connected to different portions of the active portion 340. In this regard, the gate, source, and drain portions 320, 331, 332 can be formed of the same material and on the same layer as the gate electrode 232. The active portion 340 can be formed of the same material and on the same layer as the active layer 231 of the TFT.

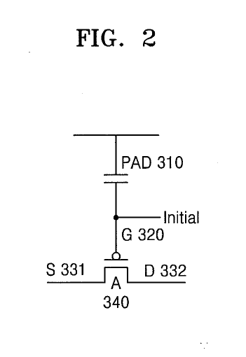

Such a structure of the contact pad test unit 300 can be represented by the circuit diagram illustrated in FIG. 2. As illustrated in the circuit diagram, the contact pad test unit 300 has a structure in which, when the capacitor, including the contact pad 310 and the gate portion 320, is discharged, an electric current flows from the source portion 331 to the drain portion 332 through the active portion 340.

The contact pad test unit 300 as such can be useful to test if the contact pad 310 is in good or bad condition.

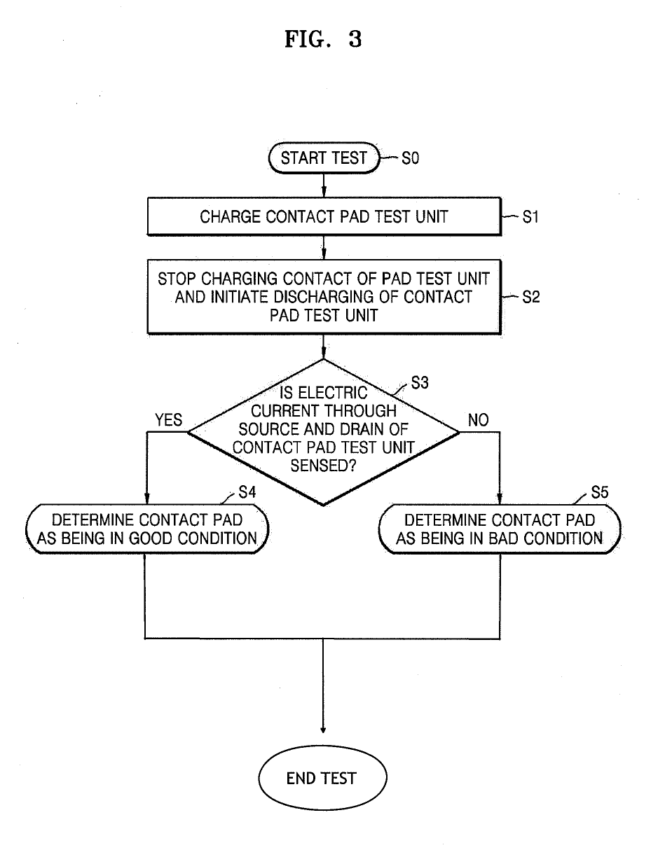

Hereinafter, a process of testing if the contact pad 310 is faulty or not will be described with reference to the flowchart of FIG. 3. Depending on embodiments, additional states may be added, others removed, or the order of the states changed in the procedure of FIG. 3. This applies to the remaining method embodiments.

First, when the contact pad 310 tested, no potential difference or voltage difference occurs between the gate portion 320 and the contact pad 310. Then, the capacitor is not charged, and therefore it is also not discharged.

In operation S0, a test of the contact pad 310 starts. In operation S1, the capacitor is charged as voltages are applied to the gate portion 320 and the contact pad 310 such that a potential difference occurs between the gate portion 320 and the contact pad 310. For example, when a potential difference is generated by applying about 8V to the contact pad 310 and about 4V to the gate portion 320, the capacitor is charged over time.

When a voltage applied to the capacitor is cut off after a period of time, in operation S2, the capacitor having been charged up to then starts to be discharged.

Then, electric current flows from the source portion 331 to the drain portion 332 via the active portion 340 facing the gate portion 320.

In operation S3, the electric current flowing from the source portion 331 to the drain portion 332 is sensed, whether the contact pad 310 is faulty or not can be easily determined.

That is, if the electric current flowing from the source portion 331 to the drain portion 332 is sensed, it means that charging and discharging of the capacitor is proceeding smoothly; in other words, the contact pad 310 configuring the capacitor works well. Accordingly, in operation S4, if electric current which flows through the drain portion 332 is sensed, the contact pad 310 is determined as being in good condition.

However, if a current flowing from the source portion 331 to the drain portion 332 is not sensed, it means that charging and discharging of the capacitor is not proceeding smoothly; in other words, the contact pad 310 configuring the capacitor is not working well. Accordingly, in operation S5, if current flowing through the drain portion 332 is not sensed, the contact pad 310 is determined as being in bad condition.

Whether the contact pad 310 is faulty or not can be easily and quickly tested with a simple operation, as described above, of sensing if electric current flows from the source portion 331 to the drain portion 332 while discharging the capacitor of the contact pad test unit 300 after charging the capacitor.

Accordingly, since whether the contact pad 310 is faulty or not can be simply determined by using the contact pad test unit 300, a speedy and accurate test can be performed, and thus, the reliability of a product can be improved.

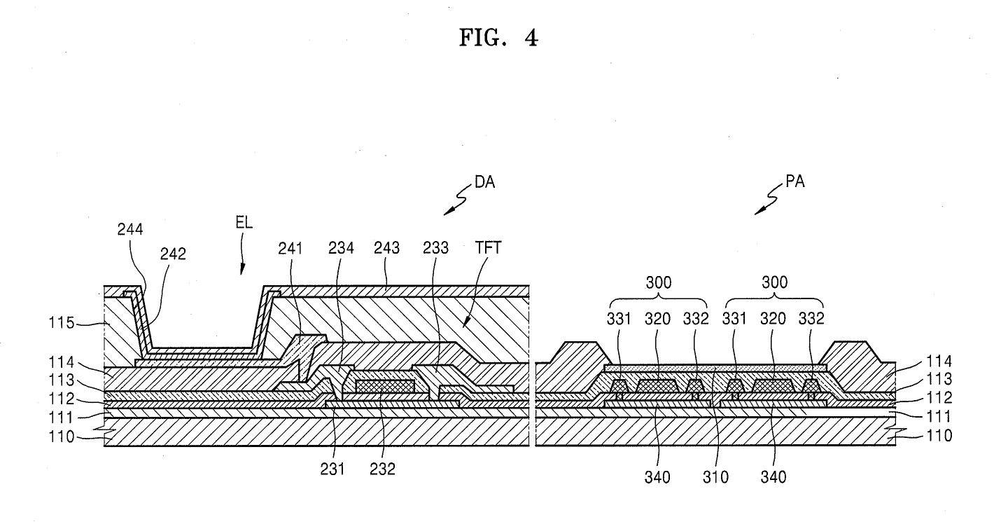

In the previous embodiment, the case in which one contact pad test unit 300 is provided with respect to one contact pad 310 was described. As shown in FIG. 4, a plurality of contact pad test units 300 can be prepared for one contact pad 310 to perform a test on the contact pad 310. That is, the number of contact pad test units 300 corresponding to the contact pad 310 can vary depending on need.

As described above, according to at least one of the disclosed embodiments, when an OLED display and a method of testing a contact pad are used, whether the contact pad is faulty or not can be easily and conveniently found out, thus allowing a speedy and accurate test and improving the reliability of a product.

It should be understood that the exemplary embodiments described therein should be considered in a descriptive sense only and not for purposes of limitation. Descriptions of features or aspects within each exemplary embodiment should typically be considered as available for other similar features or aspects in other exemplary embodiments.

While the inventive technology has been described with reference to the figures, it will be understood by those of ordinary skill in the art that various changes in form and details can be made therein without departing from the spirit and scope of the inventive concept as defined by the following claims.

What is claimed is:

1. An organic light-emitting diode (OLED) display, comprising:
a display portion formed over a substrate;
a contact pad electrically connected to the display portion; and
a contact pad test unit formed between the contact pad and the substrate and configured to generate a test current path.

2. The display of claim 1, wherein the contact pad test unit comprises a gate portion forming a capacitor with the contact pad, wherein the capacitor is configured to be charged or discharged, wherein the contact pad test unit further comprises i) an active portion facing the gate portion and ii) source and drain portions electrically connected to different portions of the active portion, and
wherein the active portion is configured to flow current from the source portion to the drain portion when the capacitor is discharged.

3. The display of claim 2, wherein the display portion comprises a thin film transistor (TFT) including an active layer, a gate electrode, a source electrode, and a drain electrode formed over the substrate, and an OLED electrically connected to the TFT.

4. The display of claim 3, wherein the gate portion, the source portion, and the drain portion of the contact pad test unit are formed of the same material and formed on the same layer as the gate electrode of the TFT.

5. The display of claim 3, wherein the active portion of the contact pad test unit is formed of the same material and formed on the same layer as the active layer of the TFT.

6. The display of claim 2, wherein the contact pad test unit includes first and second contact pad test units adjacent to each other.

7. The display of claim 2, wherein the width of the active portion is substantially the same as the width of the contact pad.

8. The display of claim 1, wherein the contact pad is formed over the entire contact pad test unit.

9. A method of testing a contact pad of an organic light-emitting diode (OLED) display, the method comprising:
preparing, over a substrate, a display portion, a contact pad electrically connected to the display portion, and a contact pad test unit configured to generate a test current path; and
verifying a current-flow state at the contact pad test unit so as to determine whether the contact pad is faulty.

10. The method of claim 9, wherein the contact pad test unit comprises a gate portion, wherein the gate portion and the contact pad comprise a capacitor configured to be charged or discharged, wherein the contact pad test unit further comprises i) an active portion facing the gate portion and ii) source and drain portions electrically connected to different portions of the active portion, and
wherein the verifying comprises generating a potential difference between the contact pad and the gate portion so as to charge the capacitor, stopping the charging of the capacitor, discharging the capacitor, and confirming if electric current is flowing from the source portion to the drain portion via the active portion based on the discharging of the capacitor.

11. The method of claim 10, further comprising:
when the electric current is flowing, determining the contact pad as not faulty; and
when the electric current is not flowing, determining that the contact pad is faulty.

12. The method of claim 9, wherein, the contact pad test unit includes first and second contact pad test units adjacent to each other, and wherein the testing is performed with the first and second contact pad test units.

13. An organic light-emitting diode (OLED) display, comprising:
a display area comprising an OLED and a thin film transistor (TFT) electrically connected to the OLED;
a pad area electrically connected to the display area and including a testing transistor and a contact pad formed over the testing transistor,
wherein the testing transistor includes a gate electrode, and wherein the gate electrode and the contact pad form a capacitor configured to store test charge configured to test the contact pad.

14. The display of claim 13, wherein the testing transistor further includes source and drain electrodes, wherein the capacitor is configured to discharge the test charge, wherein the testing transistor further includes i) an active portion facing the gate electrode and ii) source and drain electrodes electrically connected to opposing ends of the active portion, and wherein the active portion is configured to flow current including the discharged test charge from the source portion to the drain portion.

15. The display of claim 14, wherein the TFT includes an active layer, a gate electrode, a source electrode, and a drain electrode each formed over the substrate.

16. The display of claim 15, wherein the gate, source, and drain electrodes of the testing transistor are formed of the same material and formed on the same layer as the gate electrode of the TFT.

17. The display of claim 15, wherein the active portion of the testing transistor is formed of the same material and formed on the same layer as the active layer of the TFT.

18. The display of claim 14, wherein the testing transistor includes first and second testing transistors adjacent to each other.

19. The display of claim 14, wherein the width of the active portion is substantially the same as the width of the contact pad.

20. The display of claim 13, wherein the contact pad is formed over the entire testing transistor.
